(19) United States
(12) Patent Application Publication
(10) Pub. No.: US 2016/0004344 A1
(43) Pub. Date: Jan. 7, 2016

(54) TOUCH PANEL AND FABRICATION METHOD THEREOF

(71) Applicant: TPK Touch Solutions (Xiamen) Inc., Xiamen, CN (US)

(72) Inventors: Yuh-Wen Lee, Hsinchu (TW); Fengming Lin, Fuzhou (CN); Keming Ruan, Quanzhou (CN); Xianbin Xu, Xiamen (CN); Qiong Yuan, Xinyu (CN); Hongyan Lian, Xiamen (CN); Pingping Huang, Xiamen (CN)

(21) Appl. No.: 14/321,582

(22) Filed: Jul. 1, 2014

(30) Foreign Application Priority Data
Jul. 1, 2014 (CN) 201310271872.7

(51) Int. Cl. G06F 3/044; G06F 3/041; H05K 3/30

(52) U.S. Cl. CPC G06F 3/044; H05K 3/30; G06F 3/0412; G06F 2203/04103; G06F 2203/04107

(57) ABSTRACT

A touch panel is provided. The touch panel is defined as having a viewable area and a non-viewable area. The touch panel includes a protection cover and a sensing electrode layer. The protection cover includes a strengthened substrate and a functional protection layer formed on the strengthened substrate in the viewable area. The sensing electrode layer is formed on the surface of the functional protection layer in the viewable area. The disposition of the functional protection layer prevents the sensing electrode layer from failing in a broken circuit, which occurs due to the strengthened substrate chipping or cracking. Thus, the reliability of the touch panel is enhanced. Further, a method for fabricating the touch panel is also provided.

This application claims priority of the People's Republic of China Patent Application No. CN201310271872.7, filed on Jul. 1, 2013, the entirety of which is incorporated by reference herein.

### BACKGROUND OF THE INVENTION

1. Field of the Invention

The present invention relates to touch device technology, and in particular to touch devices and fabrication methods thereof.

2. Description of the Related Art

Recently, touch devices have been popularly applied in various electronic products, such as mobile phones, personal digital assistants (PDA), and handheld personal computers. One kind of conventional touch panels is fabricated by forming a sensing electrode layer directly on strengthened glass. This kind of touch panels has a single-sheet substrate structure using the strengthened glass as a substrate for forming the sensing electrode layer thereon. When the strengthened glass of the touch panels is broken or cracked due to an external force, the sensing electrode layer formed on the strengthened glass easily fails in broken circuit by losing the stability and support of the strengthened glass. Furthermore, the touch-sensing function of the touch panels also fails.

Therefore, it is desired to improve the reliability of the touch panels with the single-sheet substrate structure for increasing the practicability of the touch panels.

### BRIEF SUMMARY OF THE INVENTION

According to embodiments of the disclosure, a functional protection layer is provided in touch panels with a sensing electrode layer formed on a strengthened substrate. The functional protection layer is a clad layer or a coating layer formed of a tough, heat-resistant, and transparent material. Further, the functional protection layer is disposed between the strengthened substrate and the sensing electrode layer. According to the disposition of the functional protection layer in the embodiments of the disclosure, when the strengthened glass of the touch panels is broken or cracked due to an external force, the functional protection layer can prevent the sensing electrode layer of the touch panel from failing. Thus, the reliability of touch panels is thereby enhanced. Moreover, the touch panels of the embodiments of the disclosure can also have the advantages of light weight, low thickness and high transparency due to the touch panels having a single-sheet substrate structure.

According to embodiments of the disclosure, a touch panel is provided. The touch panel is defined as having a viewable area and a non-viewable area corresponding to the viewable area. The touch panel includes a protection cover and a sensing electrode layer, wherein the protection cover further includes a strengthened substrate and a functional protection layer formed on the surface of the strengthened substrate in the viewable area. The sensing electrode layer is formed on the surface of the functional protection layer in the viewable area. The protection cover is used as a carrier substrate for the sensing electrode layer, and the functional protection layer of the protection cover is used as a toughness substrate between the sensing electrode layer and the strengthened substrate.

According to embodiments of the disclosure, a method for fabricating a touch panel is also provided. The touch panel is defined as having a viewable area and a non-viewable area corresponding to the viewable area. The method includes providing a protection cover, wherein the protection cover comprises a strengthened substrate and a functional protection layer formed on the surface of the strengthened substrate and located in the viewable area; and forming a sensing electrode layer on the surface of the functional protection layer and located in the viewable area. The protection cover is used as a carrier substrate for the sensing electrode layer, and the functional protection layer of the protection cover is used as a toughness substrate between the sensing electrode layer and the strengthened substrate.

Using the touch panels of the disclosure, the functional protection layer disposed between the strengthened substrate and the sensing electrode layer can prevent the sensing electrode layer from failing in an open circuit due to the strengthened substrate breaking or cracking. Further, the reliability of the touch panels is thereby enhanced.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIGS. 1-3 show illustrative cross sections of touch panels according to several embodiments of the disclosure;

FIGS. 4A-4E show illustrative cross sections of intermediate stages of fabricating the touch panel of FIG. 1 according to an embodiment of the disclosure;

FIGS. 5A-5C show illustrative cross sections of intermediate stages of fabricating the touch panel of FIG. 2 according to an embodiment of the disclosure; and

FIGS. 6A-6D show illustrative cross sections of intermediate stages of fabricating the touch panel of FIG. 3 according to an embodiment of the disclosure.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

In the accompanying drawings, in order to clearly illustrate the characteristics of embodiments of the disclosure, each element in the touch panels may not be drawn to scale. Moreover, in the descriptions that follow, the orientations of “on”, “over”, “above”, “under” and “below” are used for representing the relationship between the relative positions of each element in the touch panels, and are not used to limit the disclosure. However, in an actual application of the touch panels, the protection cover 100 is disposed at the top of the touch device for users.

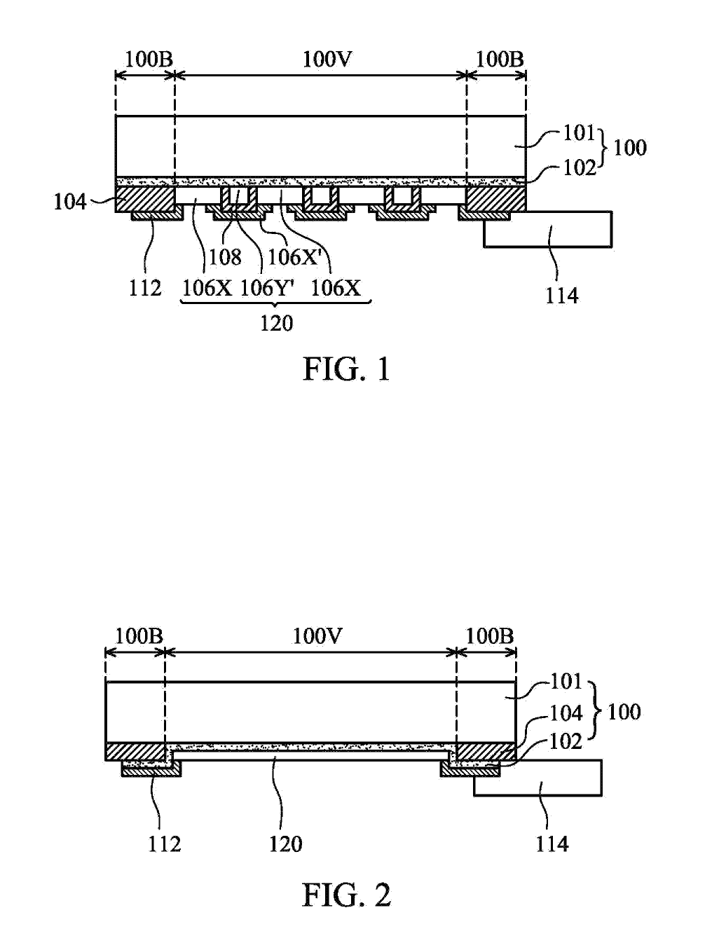

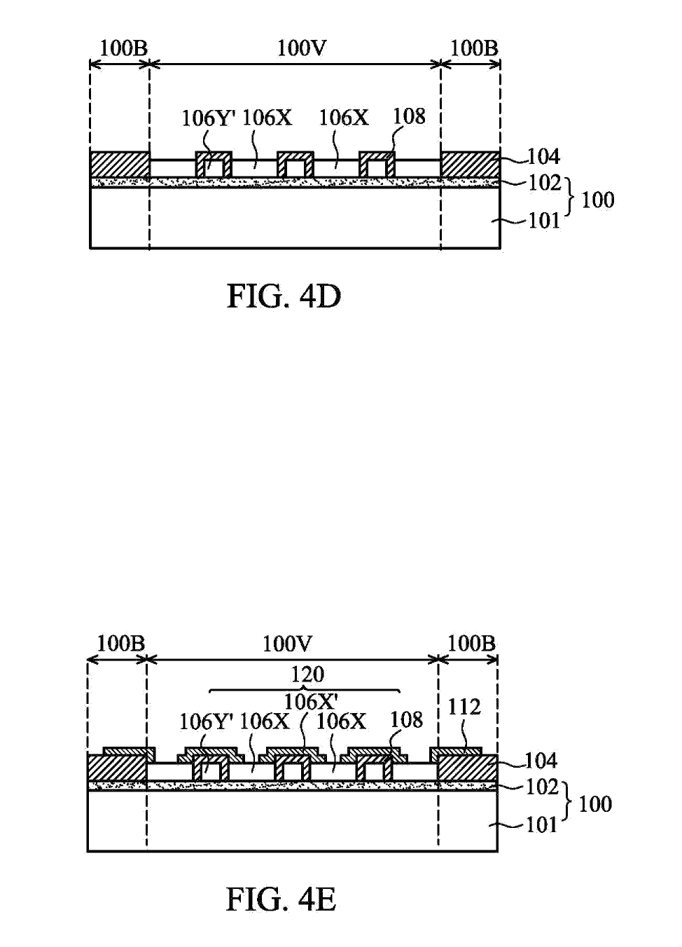

In FIGS. 1-3, the structures of touch panels of the embodiments are illustrated by disposing a strengthened substrate 101 at the top of the touch panels. However, in FIGS. 4A-6D, the methods for fabricating the touch panels of the embodiments are illustrated by disposing the strengthened substrate 101 at the bottom of the touch panels.

Referring to FIG. 1, a cross section of a touch panel according to an embodiment of the disclosure is shown. The touch panel can be defined as having a viewable area 100V and a non-viewable area 100B corresponding to the viewable area by the area of a decorative layer 104, wherein the decorative layer 104 is disposed in the non-viewable area 100B and the other area is the viewable area 100V. The non-viewable area 100B is generally designed to be located on at least one side of the viewable area 100V.

The touch panel of the embodiment includes a protection cover 100 and a sensing electrode layer 120, wherein the protection cover 100 includes a strengthened substrate 101 and a functional protection layer 102. The functional protection layer 102 is formed on a lower surface of the strengthened substrate 101 in the viewable area 100V. The sensing electrode layer 120 is formed on a lower surface of the functional protection layer 102 in the viewable area 100V. As such, the protection cover 100 of the embodiment can be used as a carrier substrate for the sensing electrode layer 120. The functional protection layer 102 of the protection cover 100 is used as a toughness substrate between the sensing electrode layer 120 and the strengthened substrate 101. The functional protection layer 102 is a clad layer or a coating layer formed of a transparent heat-resistant material, preferably a high-toughness, transparent and heat-resistant layer. The transparent heat-resistant material is for example polyimide resin, a low-viscosity resin, titanium dioxide, etc.

From the above-mentioned structure, when the protection cover 100 of the embodiment is damaged by an external force to cause the strengthened substrate 101 to break or crack, the functional protection layer 102 would not fail due to the damage of the strengthened substrate 101 because the functional protection layer 102 has a toughness character. Conversely, the functional protection layer 102 can further be used as a carrier base for the sensing electrode layer 120 to maintain the touch-sensing function of the sensing electrode layer 120. Indeed, the functional protection layer 102 can protect the sensing electrode layer 120.

The functional protection layer 102 of the embodiment can further extend to at least a part of the non-viewable area 100B and be formed on the lower surface of the strengthened substrate 101. In other words, the functional protection layer 102 of the embodiment is formed to completely cover the lower surface of the strengthened substrate 101. In addition, the decorative layer 104 is formed on a lower surface of the functional protection layer 102. The decorative layer 104 can be formed from printing ink by a printing process, in which case the decorative layer 104 has a thickness of about 5 μm to about 10 μm. The decorative layer 104 can also be formed from an opaque photoresist material by a photolithography process, in which case the decorative layer 104 has a thickness of about 1 μm to about 2 μm.

The sensing electrode layer 120 of the embodiment is illustrated by a single-layered transparent conductive structure. In the other embodiment, the sensing electrode layer 120 can be designed as a two-layered transparent conductive structure. It is not used to limit the scope of the disclosure. In an embodiment, the single-layered transparent conductive structure of the sensing electrode layer 120 includes a plurality of first sensing electrodes formed of indium tin oxide (ITO) arranged along a first-axial direction, for example the X-axis, wherein each of the first sensing electrodes includes a plurality of first conductive units 106X separated from each other and a plurality of jumpers 106X′ for electrically connecting any two adjacent first conductive units 106X in the first-axial direction. The sensing electrode layer 120 further includes a plurality of second sensing electrodes arranged along a second-axial direction, for example the Y-axis, wherein each of the second sensing electrodes includes a plurality of second conductive units (not shown) and a plurality of connection lines 106Y′ for electrically connecting any two adjacent second conductive units in the second-axial direction. The jumpers 106X′ and the connection lines 106Y′ crisscross.

The sensing electrode layer 120 further includes a plurality of electrical isolation structures 108. The electrical isolation structures 108 are individually disposed between each of the connection lines 106Y′ and each of the jumpers 106X′ which are crisscrossed to prevent a short circuit from occurring between the first sensing electrodes arranged along the first-axial direction, for example the X-axis, and the second sensing electrodes arranged along the second-axial direction, for example the Y-axis. In an embodiment, the structure and pattern of each element of the sensing electrode layer 120 can be formed by a deposition, photolithography and etching process.

Next, as shown in FIG. 1 again, the wiring layer 112 of the embodiment is formed on a lower surface of the decorative layer 104 in the non-viewable area 100B. The wiring layer 112 further extends to the viewable area 100V and under the sensing electrode layer 120 for electrically connecting to the sensing electrode layer 120. The wiring layer 112 includes a plurality of metal lines and a plurality of bonding pads. The metal lines are electrically connected to the sensing electrode layer 120, and the bonding pads are respectively connected to the metal lines. Then, the bonding pads are bonded to a flexible printed circuit (FPC) 114. As such, a touch-signal obtained from the sensing electrode layer 120 is transmitted to an external circuit (not shown) through the flexible printed circuit (FPC) 114.

According to the structure of the embodiment, the functional protection layer 102 extends from the viewable area 100V of the touch panel to at least a part of the non-viewable area 100B, or to cover all of the non-viewable area 100B. When the strengthened substrate 101 is broken or cracked, the functional protection layer 102 not only can protect the sensing electrode layer 120 in the viewable area 100V, but it also can be used as a toughness substrate between the wiring layer 112 and the strengthened substrate 101. The functional protection layer 102 can be used as a carrier base for continuously supporting the wiring layer 112. The signal-transmitting function of the wiring layer 112 is maintained by the functional protection layer 102 to protect the wiring layer 112.

Moreover, the functional protection layer 102 is formed of a tough, transparent, heat-resistant material. The tough, transparent, heat-resistant material has a good adhesion to the strengthened substrate 101 and the adhesion of the sensing electrode layer 120 to the tough material is higher than the adhesion of the sensing electrode layer 120 to the strengthened substrate 101. Therefore, it can effectively prevent the sensing electrode layer 120 from peeling. The reliability of the sensing electrode layer 120 is thereby enhanced. In addition, the high-toughness, transparent and heat-resistant material has a heat-resistant temperature of higher than about 240° C., such that the functional protection layer 102 can resist the processing temperature when subsequently forming the sensing electrode layer 120 and the wiring layer 112.

In another embodiment, the sensing electrode layer 120 further extends to at least a part of the non-viewable area 100B. The sensing electrode layer 120 in the non-viewable area 100B is formed on the lower surface of the decorative layer 104. Therefore, the wiring layer 112 of the embodiment is completely located in the non-viewable area 100B and formed on the lower surface of the decorative layer 104 for electrically connecting to the sensing electrode layer 120.

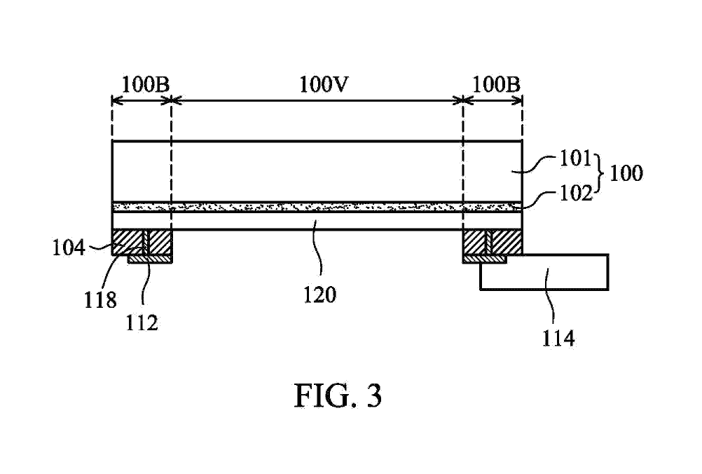

Referring to FIG. 2, a cross section of a touch panel according to another embodiment of the disclosure is shown. The structure of the touch panel of the embodiment is approximately the same as that of the embodiment as shown in FIG. 1. The difference between FIG. 2 and FIG. 1 is that the protection cover 100 of the embodiment of FIG. 2 further includes a decorative layer 104 used to define a non-viewable area 100B of the touch panel and the decorative layer 104 is firstly formed on a lower surface of the strengthened substrate 101 and then the functional protection layer 102 is formed. In fact, the functional protection layer 102 in the viewable area 100V is formed on the lower surface of the strengthened substrate 101 and the functional protection layer 102 in the non-viewable area 100B is formed on a lower surface of the decorative layer 104.

In addition, the functional protection layer 102 of the embodiment is formed after forming the decorative layer 104, such that the wiring layer 112, which is subsequently disposed in the non-viewable area 100B, is formed on a lower surface of the functional protection layer 102 and further extends to the viewable area 100V for electrically connecting to the sensing electrode layer 120. Moreover, although a detailed structure of the sensing electrode layer 120 is not shown in the embodiment of FIG. 2, the sensing electrode layer 120 may be any structural design required for touch panels. It is not used to limit the scope of the invention. In another embodiment, the wiring layer 112 is disposed only in the non-viewable area 100B, but the sensing electrode layer 120 extends to the non-viewable area 100B. Through the sensing electrode layer 120 extending to the non-viewable area 100B, the wiring layer 112 can also be electrically connected to the sensing electrode layer 120.

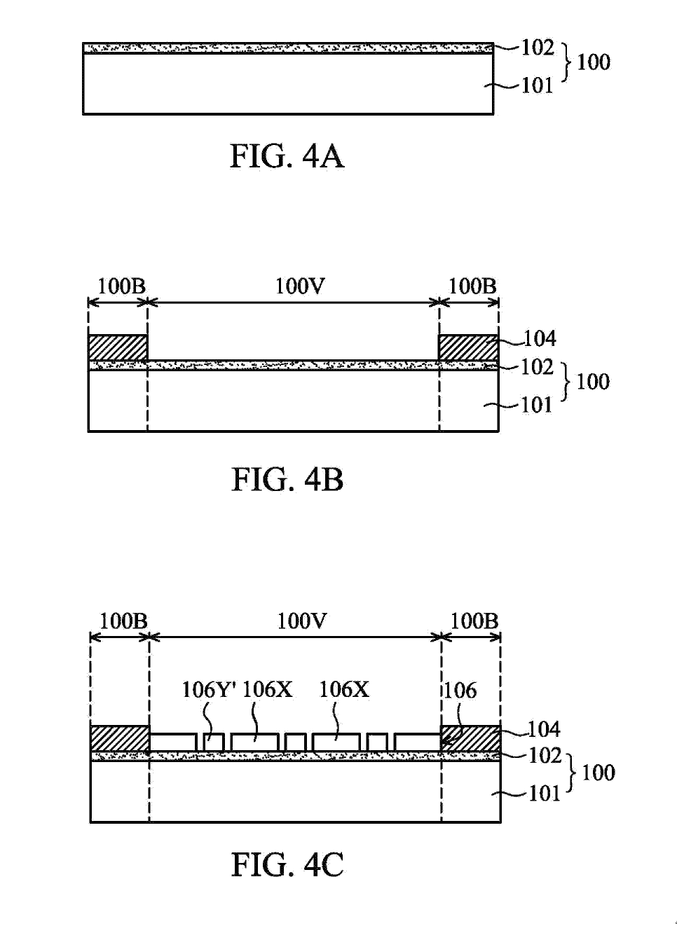

Referring to FIG. 3, a cross section of a touch panel according to another embodiment of the disclosure is shown. The touch panel of the embodiment has a structure approximately the same as that of the embodiment as shown in FIG. 1. The difference between FIG. 3 and FIG. 1 is that the sensing electrode layer 120 of the embodiment of FIG. 3 further extends to at least a part of the non-viewable area 100B. The sensing electrode layer 120 in the non-viewable area 100B is formed on a lower surface of the functional protection layer 102. The decorative layer 104 is further formed on a lower surface of the sensing electrode layer 120. As such, the structure of the embodiment is formed by firstly forming the sensing electrode layer 120 and then forming the decorative layer 104.

Furthermore, the wiring layer 112 of the embodiment is further formed on a lower surface of the decorative layer 104. In other words, the insulating decorative layer 104 is disposed between the wiring layer 112 and the sensing electrode layer 120. Therefore, the decorative layer 104 of the embodiment further includes a conductive part 118 disposed for corresponding to each of the sensing electrodes of the sensing electrode layer 120. The conductive part 118 can be formed by filling a through hole in the decorative layer 104 with a conductive material, for example conductive glue. The wiring layer 112 can be electrically connected to the sensing electrode layer 120 through the conductive part 118. In another embodiment, the conductive part 118 can be directly formed of the wiring layer 112 combined with the through hole. In other words, the conductive material filling in the through hole can be directly obtained from the material of the wiring layer 112. As such, when the wiring layer 112 is formed on the surface of the decorative layer 104, the wiring layer also fills in the through hole to form the conductive part 118.

In the above-mentioned embodiments, the functional protection layer 102 can extend from the viewable area 100V to at least a part of the non-viewable area 100B, or cover all of the non-viewable area 100B. Thus, the functional protection layer 102 can completely cover the sensing electrode layer 120 and the wiring layer 112 in their relative position. As such, when the strengthened substrate 101 is broken or cracked, the functional protection layer 102 can continuously provide a complete carrier base for supporting the sensing electrode layer 120 and the wiring layer 112. It can prevent the sensing electrode layer 120 and the wiring layer 112 from breaking or peeling to lose the functions thereof. Thus, the reliability of the touch panel is thereby enhanced.

In addition, the touch panels of the embodiments of the disclosure can be capacitive touch panels. All elements of the touch panel are formed on the surface of one side of the strengthened substrate 101 in sequence to form a single-sheet substrate structure. The surface of the other side of the strengthened substrate 101 is used as the touch side of the touch panel.

FIGS. 4A-4E show cross sections of intermediate stages of fabricating the touch panel of FIG. 1 according to an embodiment. Referring to FIG. 4A, firstly, a protection cover 100 is provided. The protection cover 100 includes a strengthened substrate 101 and a functional protection layer 102, wherein the functional protection layer 102 is formed on an upper surface of the strengthened substrate 101. The strengthened substrate 101 is for example a strengthened glass substrate and the material of the functional protection layer 102 can be a polyimide (PI) resin. The polyimide (PI) resin material can be coated on the strengthened substrate 101 by a coating process. Then, the coating layer is baked to remove a solvent in the polyimide (PI) resin material to form a thin polyimide (PI) resin layer as the functional protection layer 102. The material of the functional protection layer 102 is a high-toughness, transparent and heat-resistant material which has a good adhesion to the strengthened glass substrate 101. Moreover, the adhesion of the transparent conductive material to the functional protection layer 102 is higher than that directly to the strengthened glass substrate 101. In which case, the transparent conductive material is for example indium tin oxide (ITO) which is used to subsequently form a sensing electrode layer 120. Therefore, the functional protection layer 102 can effectively prevent the sensing electrode layer 120 from peeling.

Moreover, the material of the functional protection layer 102 can be a low viscosity resin. The low viscosity resin is different from the optical clear adhesive (OCA) used in conventional touch panels for bonding a touch-function substrate with a cover plate. The optical clear adhesive (OCA) is a viscolloid and usually made of silicone or acrylic resin. However, the functional protection layer 102 of the embodiments is a clad layer or a coating layer of a high-toughness, transparent and heat-resistant material, not a glue for bonding.

In another embodiment, the material of the functional protection layer 102 can be titanium dioxide, which can be formed by a sputtering method. The titanium dioxide material has several advantages of low thickness, good optical character, high transparency, etc. Moreover, titanium dioxide has a good UV-resistant ability. As such, the touch panels using titanium dioxide have a long lifetime. In addition, titanium dioxide is dense. When titanium dioxide is firstly formed on the strengthened glass substrate 101 and then other touch elements are subsequently formed thereon, it can prevent the surface of the strengthened glass substrate 101 from being etched by an acid or a base solution used in the fabrication process of the touch panel. The strength of all structures of the touch panels is thereby enhanced.

Moreover, the material of the functional protection layer 102 of the embodiment can resist a high-temperature of a subsequent process for forming the sensing electrode layer 120. In an embodiment, a heat-resistant temperature of the material of the functional protection layer 102 is more than about 240° C.

Referring to FIG. 4B, a decorative layer 104 is formed on the functional protection layer 102 to define the non-viewable area 100B of the touch panel. The non-viewable area 100B is usually disposed for corresponding to at least one side of the viewable area 100V. The decorative layer 104 can be formed by a photolithography process. The material used in forming the decorative layer 104 is, for example, an opaque photoresist material. The decorative layer 104 formed thereby has a thickness of about 1 μm to about 2 μm. In another embodiment, the decorative layer 104 can be formed by a printing process. The material used in forming the decorative layer 104 is for example an insulating printing ink. The decorative layer 104 formed thereby has a thickness of about 5 μm to about 10 μm. In addition, the functional protection layer 102 is designed to be located at least in the view/able area 100V. However, the functional protection layer 102 of the embodiments is not only located in the viewable area 100V, but also further extends to the non-viewable area 100B.

Referring to FIG. 4C, a transparent conductive layer 106 is firstly deposited on the functional protection layer 102. Then, the transparent conductive layer 106 is patterned by a photolithography and etching process to form a plurality of first conductive units 106X separated from each other along a first-axial direction, for example the X-axis, and a plurality of second sensing electrodes arranged along a second-axial direction, for example the Y-axis, wherein each of the second sensing electrodes includes a plurality of second conductive units (not shown) and a plurality of connection lines 106Y′ for electrically connecting any two adjacent second conductive units in the second-axial direction.

Referring to FIG. 4D, a plurality of electrical isolation structures 108 is formed on the functional protection layer 102 in the viewable area 100V. These electrical isolation structures 108 are individually formed above each of the connection lines 106Y′ of the second conductive units. The electrical isolation structures 108 can be formed by a photolithography process. The material used in forming the electrical isolation structures 108 is, for example, a transparent insulating material.

Referring to FIG. 4E, a plurality of jumpers 106X′ is formed on the electrical isolation structures 108. The jumpers 106X′ are used for electrically connecting any two adjacent first conductive units 106X in the first-axial direction to form the first sensing electrodes. The jumpers 106X′ and the connection lines 106Y′ of the second sensing electrodes are crisscrossed with each other. Moreover, the jumpers 106X′ and the connection lines 106Y′ are electrically isolated from each other by the electrical isolation structures 108. As such, the first sensing electrodes, the second sensing electrodes and the electrical isolation structures 108 constitute the sensing electrode layer 120 formed on the surface of the functional protection layer 102 in the viewable area 100V. In addition, the sensing electrode layer 120 of the embodiment is designed to form only in the viewable area 100V. However, in another embodiment, the sensing electrode layer 120 can be designed to extend to at least a part of the non-viewable area 100B and be formed on the surface of the decorative layer 104.

Moreover, after the sensing electrode layer 120 is completed, a wiring layer 112 is further formed on the decorative layer 104 for electrically connecting to the sensing electrode layer 120. The wiring layer 112 of the embodiment extends to the viewable area 100V for electrically connecting to the sensing electrode layer 120. In an embodiment, the jumpers 106X′ and the wiring layer 112 can be formed by a deposition, a photolithography and an etching process at the same time. The materials for forming the jumpers 106X′ and the wiring layer 112 are for example a metal. Next, the wiring layer 112 is bonded to a flexible printed circuit (FPC) 114 as shown in FIG. 1 to complete the touch panel of FIG. 1.

In the touch panel fabricated by the embodiment, the functional protection layer 102 in the non-viewable area 100B is formed before the decorative layer 104 and the wiring layer 112 are formed. The protection cover 100 of the touch panel is used as a carrier substrate for supporting the sensing electrode layer 120. The functional protection layer 102 of the protection cover 100 is used as a toughness substrate between the sensing electrode layer 120, the wiring layer 112 and the strengthened substrate 101 for protecting the sensing electrode layer 120 and the wiring layer 112.

In the following embodiments, different process sequences corresponding to different structures of touch panels are illustrated. The materials, the sizes and the technologies used in the following embodiments can be the same as those of the above-mentioned embodiments, and are not repeated again to simplify the illustration.

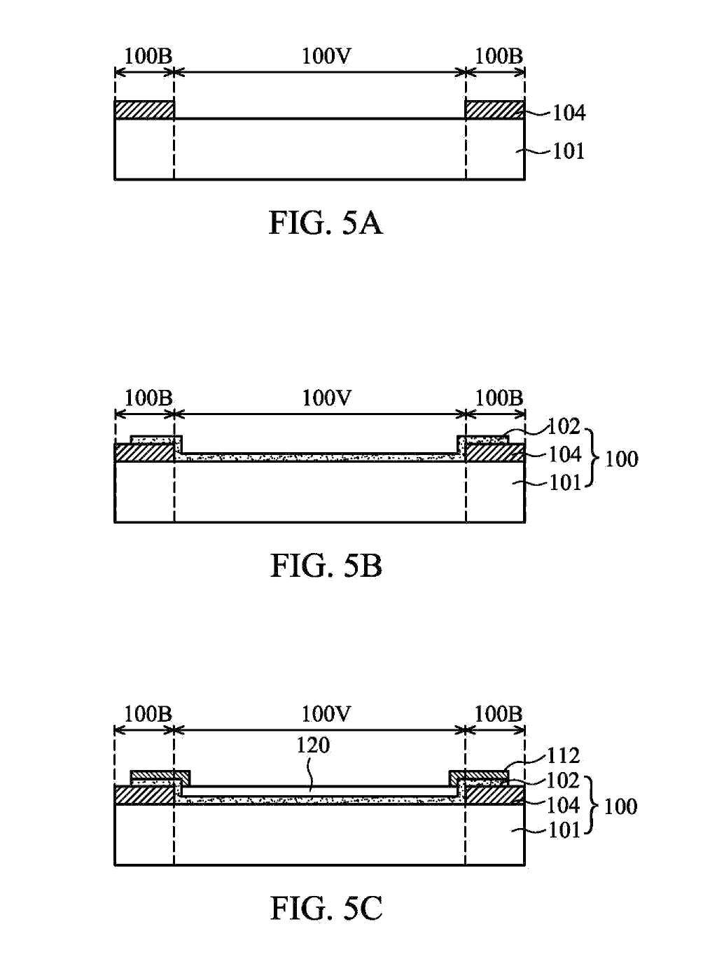

FIGS. 5A-5C shows cross sections of intermediate stages of fabricating the touch panel of FIG. 2 according to an embodiment. Referring to FIGS. 5A and 5B, firstly, a protection cover 100 is provided. The protection cover 100 includes a strengthened substrate 101, a decorative layer 104 and a functional protection layer 102. As shown in FIG. 5A, the decorative layer 104 is formed on an upper surface of the strengthened substrate 101 to define the non-viewable area 100B of the touch panel. Next, as shown in FIG. 5B, the functional protection layer 102 is formed. The functional protection layer 102 in the viewable area 100V is formed on the upper surface of the strengthened substrate 101. The functional protection layer 102 further extends to at least a part of the non-viewable area 100B and be formed on an upper surface of the decorative layer 104.

Next, as shown in FIG. 5C, a sensing electrode layer 120 and a wiring layer 112 are formed on an upper surface of the functional protection layer 102. The sensing electrode layer 120 of the embodiment is designed to form only in the viewable area 100V. The wiring layer 112 of the embodiment is designed to not only form in the non-viewable area 100B, but also extend to the viewable area 100V for electrically connecting to the sensing electrode layer 120. In another embodiment, the sensing electrode layer 120 is designed to extend to at least a part of the non-viewable area 100B for electrically connecting to the wiring layer 112 only located in the non-viewable area 100B. In addition, although a detailed structure of the sensing electrode layer 120 is not shown in FIG. 5C, the sensing electrode layer 120 can be designed to be any kind of structure required for touch panels. Next, the wiring layer 112 is bonded to a flexible printed circuit (FPC) 114 as shown in FIG. 2 to complete the touch panel of FIG. 2.

In the touch panel fabricated by the embodiment, the functional protection layer 102 in the non-viewable area 100B is formed after the decorative layer 104 is formed and before forming the wiring layer 112. The functional protection layer 102 of the protection cover 100 can be used as a toughness substrate between the sensing electrode layer 120, the wiring layer 112 and the strengthened substrate 101 to achieve an effect of protecting the sensing electrode layer 120 and the wiring layer 112.

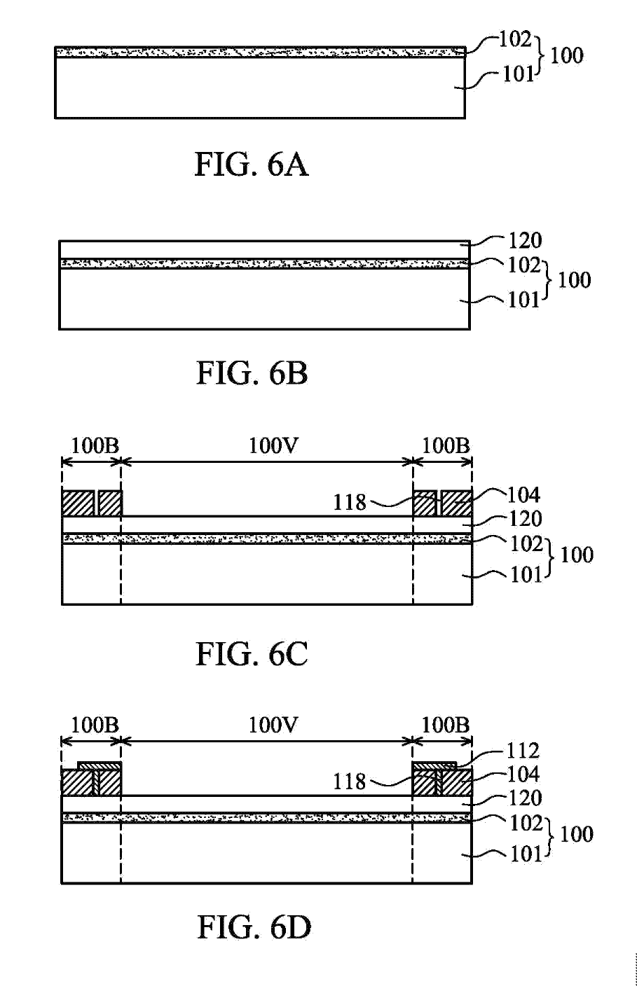

As shown in FIGS. 6A-6D, cross sections of intermediate stages of fabricating the touch panel of FIG. 3 according to an embodiment are shown. Referring to FIG. 6A, firstly, a protection cover 100 is provided. The protection cover 100 includes a strengthened substrate 101 and a functional protection layer 102. The functional protection layer 102 is formed on an upper surface of the strengthened substrate 101.

Referring to FIG. 6B, a sensing electrode layer 120 is formed on an upper surface of the functional protection layer 102. Although a detail structure of the sensing electrode layer 120 is not shown in FIG. 6B, the sensing electrode layer 120 can be designed to be any kind of structure required for touch panels.

Referring to FIG. 6C, a decorative layer 104 is formed on the surface of the sensing electrode layer 120 to define the non-viewable area 100B of the touch panel. The decorative layer 104 of the embodiment includes a conductive part 118 for corresponding to each of the sensing electrodes of the sensing electrode layer 120. The conductive part 118 can be formed by filling a through hole in the decorative layer 104 with a conductive material, for example conductive glue. Moreover, in the embodiment, the functional protection layer 102 and the sensing electrode layer 120 can extend to at least a part of the non-viewable area 100B. An extending area of the functional protection layer 102 is preferably larger than or equal to an extending area of the sensing electrode layer 120.

Referring to FIG. 6D, a wiring layer 112 is formed on the surface of the decorative layer 104. The wiring layer 112 electrically connects to the sensing electrode layer 120 through the conductive part 118. In addition, as mentioned above, the conductive part 118 of the embodiment can be formed by filling the through hole with a conductive material. In another embodiment, the material used in forming the wiring layer 112, for example a metal material, can be directly deposited on the decorative layer 104 and fill in a through hole of the decorative layer 104 to form the wiring layer 112 and the conductive part 118. Next, the wiring layer 112 is bonded to a flexible printed circuit (FPC) 114 as shown in FIG. 3 to complete the touch panel of FIG. 3.

In the touch panel fabricated by the embodiment, the functional protection layer 102 in the non-viewable area 100B is formed before forming the sensing electrode layer 120, the decorative layer 104 and the wiring layer 112. The functional protection layer 102 of the protection cover 100 can be used as a toughness substrate between the sensing electrode layer 120, the wiring layer 112 and the strengthened substrate 101 to achieve an effect of protecting the sensing electrode layer 120 and the wiring layer 112.

As per the above description, and according to the embodiments of the disclosure, the functional protection layer is disposed between the strengthened substrate of the protection cover and the sensing electrode layer in the touch panels having the single-sheet substrate structure with the sensing electrode layer formed on the protection cover. The functional protection layer can extend from an active area having the sensing electrode layer to a trace area at the periphery of the active area. As such, the functional protection layer can completely cover the areas of the sensing electrode layer and the wiring layer.

The functional protection layer of the disclosure is a clad layer or a coating layer formed of a high-toughness, transparent and heat-resistant material. The high-toughness, transparent and heat-resistant material has good adhesion to the protection cover made of glass. Moreover, the adhesion of the sensing electrode layer to the high-toughness, transparent and heat-resistant material is higher than that to the glass protection cover. Therefore, when the strengthened substrate is broken or cracked, the functional protection layer of the disclosure can prevent the sensing electrode layer and the wiring layer from breaking or peeling, i.e. make sure the sensing electrode layer and the wiring layer are not affected by the strengthened substrate. Thus, the disposition of the functional protection layer can effectively prevent the touch-function of the touch panels from failing. The reliability of the touch panels is thereby enhanced. Moreover, the touch panels of the embodiments of the disclosure can also keep the advantages of the touch panels with the single-sheet substrate structure, i.e. light weight, low thickness and high transmission of light.

Referring to Table 1 and Table 2, according to an analysis of the results of a Drop Ball Test, the functional protection layer disposed between the strengthened substrate and the sensing electrode layer can increase the strength of the strengthened substrate. As shown in Table 1 and Table 2, the functional protection layer is titanium dioxide, for example. With the same test conditions, the average height in the Drop Ball Test needed to break the strengthened substrate of Example 1 without a functional protection layer is 17.9 cm, and the average height in the Drop Ball Test needed to break the strengthened substrate of Example 2 with a functional protection layer of titanium dioxide is 34.6 cm. From the results in Table 1 and Table 2, touch panels using the strengthened substrate with the functional protection layer can have a better mechanical strength.

TABLE 1
Example 1: a strengthened substrate (0.55 mm) + a sensing electrode layer
Drop ball weight: 130 g
Drop ball height: an initial height of 10 cm with an increasing height of
5 cm for every iteration, the drop ball height was increased until the
strengthened substrate was broken.

| Sample | Broken height (cm) |
|---|---|
| 1 | 15 |
| 2 | 15 |
| 3 | 20 |
| 4 | 20 |
| 5 | 20 |
| 6 | 20 |
| 7 | 15 |
| 8 | 20 |
| 9 | 15 |
| 10 | 15 |
| 11 | 25 |
| 12 | 15 |

maximum height: 25 cm;
minimum height: 15 cm;
average height: 17.9 cm

TABLE 2
Example 2: a strengthened substrate (0.55 mm) + a functional protection
layer (titanium dioxide) + a sensing electrode layer
Drop ball weight: 130 g
Drop ball height: an initial height of 10 cm with an increasing height of
5 cm for every iteration, the drop ball height was increased until the
strengthened substrate was broken.

| Sample | Broken height (cm) |
|---|---|
| 1 | 25 |
| 2 | 30 |
| 3 | 35 |
| 4 | 30 |
| 5 | 45 |
| 6 | 25 |
| 7 | 45 |
| 8 | 30 |
| 9 | 25 |
| 10 | 50 |
| 11 | 40 |
| 12 | 35 |

maximum height: 50 cm;
minimum height: 25 cm;
average height: 34.6 cm

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A touch panel, defined to have a viewable area and a non-viewable area corresponding to the viewable area, the touch device comprising:
a protection cover, comprising:
a strengthened substrate; and
a functional protection layer formed on a surface of the strengthened substrate in the viewable area; and
a sensing electrode layer formed on a surface of the functional protection layer in the viewable area,
wherein the protection cover is a carrier substrate for the sensing electrode layer, and the functional protection layer of the protection cover is a toughness substrate between the sensing electrode layer and the strengthened substrate.

2. The touch panel of claim 1, wherein the functional protection layer is a clad layer or a coating layer of a transparent heat-resistant material.

3. The touch panel of claim 1, wherein the functional protection layer is polyimide resin, a low viscosity resin or titanium dioxide.

4. The touch panel of claim 1, wherein the functional protection layer further extends to at least a part of the non-viewable area.

5. The touch panel of claim 4, wherein the functional protection layer in the non-viewable area is formed on the surface of the strengthened substrate.

6. The touch panel of claim 5, wherein the protection cover further comprises a decorative layer to define the non-viewable area, and wherein the decorative layer is formed on the surface of the functional protection layer.

7. The touch panel of claim 6, wherein the sensing electrode layer further extends to at least a part of the non-viewable area, and the sensing electrode layer in the non-viewable area is formed on a surface of the decorative layer.

8. The touch panel of claim 5, further comprising a decorative layer to define the non-viewable area, wherein the sensing electrode layer further extends to at least a part of the non-viewable area, the sensing electrode layer in the non-viewable area is formed on the surface of the functional protection layer, and the decorative layer is formed on a surface of the sensing electrode layer.

9. The touch panel of claim 8, further comprising a wiring layer formed on a surface of the decorative layer for electrically connecting to the sensing electrode layer.

10. The touch panel of claim 9, wherein the decorative layer includes a conductive part and the wiring layer is electrically connected to the sensing electrode layer through the conductive part.

11. The touch panel of claim 4, wherein the protection cover further comprises a decorative layer to define the non-viewable area, the decorative layer is formed on the surface of the strengthened substrate, and the functional protection layer in the non-viewable area is formed on a surface of the decorative layer.

12. The touch panel of claim 11, wherein the sensing electrode layer further extends to at least a part of the non-viewable area, and the sensing electrode layer in the non-viewable area is formed on the surface of the functional protection layer.

13. The touch panel of claim 1, wherein the sensing electrode layer comprises a single-layered transparent conductive structure or a two-layered transparent conductive structure.

14. A method for fabricating a touch panel, wherein the touch panel is defined to have a viewable area and a non-viewable area corresponding to the viewable area, the method comprising:
providing a protection cover, wherein the protection cover comprises a strengthened substrate and a functional protection layer formed on a surface of the strengthened substrate and located at least in the viewable area; and
forming a sensing electrode layer on a surface of the functional protection layer and located at least in the viewable area,
wherein the protection cover is a carrier substrate for the sensing electrode layer, and the functional protection layer of the protection cover is a toughness substrate between the sensing electrode layer and the strengthened substrate.

15. The method of claim 14, wherein the functional protection layer is formed by cladding or coating a transparent heat-resistant material.

16. The method of claim 14, wherein the functional protection layer further extends to the non-viewable area.

17. The method of claim 16, further comprising:
forming a decorative layer to define the non-viewable area; and
forming a wiring layer to electrically connect to the sensing electrode layer.

18. The method of claim 17, wherein the functional protection layer in the non-viewable area is formed at least before forming the decorative layer and the wiring layer.

19. The method of claim 17, wherein the functional protection layer in the non-viewable area is formed after forming the decorative layer and at least before forming the wiring layer.
